(19) United States
(12) Patent Application Publication
(10) Pub. No.: US 2025/0347735 A1
(43) Pub. Date: Nov. 13, 2025

(54) SYSTEMS AND METHODS INCLUDING IDENTIFICATION CHIPS IN ADAPTER CABLES

(71) Applicant: DIT-MCO International LLC, Kansas City, MO (US)

(72) Inventors: David Alan Shier, Lee's Summit, MO (US); Dalton Brineger, Grain Valley, MO (US)

(21) Appl. No.: 19/204,176

(22) Filed: May 9, 2025

Related U.S. Application Data
(60) Provisional application No. 63/646,315, filed on May 13, 2024.

(51) Int. Cl. G01R 31/28; G01R 35/00

(52) U.S. Cl. CPC G01R 31/2844; G01R 31/2834; G01R 35/005

(57) ABSTRACT

Various embodiments provide a testing system for evaluating electrical wiring systems. The system can include an analyzer unit, a first adapter cable, and a second adapter cable. The analyzer unit can include an identification chip reader. The identification chip reader can be configured to read and determine the identity of an identification chip that is part of an adapter cable that is connected to the analyzer unit. Various other embodiments are also provided.

### RELATED APPLICATIONS

This application claims the benefit of U.S. Provisional Application No. 63/646,315, filed May 13, 2024, the content of which is incorporated herein by reference in its entirety.

### FIELD

Embodiments herein relate to systems and methods including adapter cables with identification chips.

### BACKGROUND

In the manufacturing or installation of electrical wiring systems and harnesses, it is necessary to verify separate conductors (e.g., networks or circuits) are isolated from each other. Analyzers, also referred to as automatic test equipment (ATE), run automated test scripts that include measuring electrical characteristics in order to predict continuity. ATE requires a plurality of interface adapters to connect to all the separate conductors to be tested simultaneously, such that a test script can run automatically with little or no operator intervention after the test is started.

Due to the various different configurations of connections with wiring harnesses, users have been forced to utilize various different adapter cables for connecting the ATE to the different wire harness connections.

### SUMMARY

Various embodiments provide a testing system for evaluating electrical wiring systems. The system can include an analyzer unit, wherein the analyzer unit includes: a plurality of test pins, an identification chip reader, wherein the identification chip reader is configured to read and determine the identity of an identification chip, and a processing element, and a first adapter cable, wherein the first adapter cable includes: an analyzer interface, wherein the analyzer interface is configured to connect with a portion of the plurality of test pins, a UUT interface, a central cable extending between and electrically coupling the analyzer interface with the UUT interface, and an identification chip coupled to the analyzer interface, the UUT interface, or the central cable, wherein the identification chip includes a unique identifier, a second adapter cable, wherein the second adapter cable includes: an analyzer interface, wherein the analyzer interface is configured to connect with a portion of the plurality of test pins, a UUT interface, a central cable extending between and electrically coupling the analyzer interface with the UUT interface, and an identification chip coupled to the analyzer interface, the UUT interface, or the central cable, wherein the identification chip includes a unique identifier, wherein the analyzer interface of the first adapter cable is structurally different from the analyzer interface of the second adapter cable, wherein a connection of the identification chip reader is structurally different from the plurality of test pins.

In an embodiment, the identification chip of the first adapter cable is disposed within the central cable.

In an embodiment, the identification chip of the first adapter cable is disposed within the analyzer interface.

In an embodiment, the identification chip of the first adapter cable is coupled to the first adapter cable with an extension.

In an embodiment, the identification chip reader requires physical contact of the identification chip reader with the identification chip.

In an embodiment, the identification chip of the first adapter cable and/or the identification chip of the second adapter cable is a 1-wire chip.

In an embodiment, the identification chip of the first adapter cable and/or the identification chip of the second adapter cable includes read-only capabilities.

In an embodiment, the identification chip of the first adapter cable and/or the identification chip of the second adapter cable is a RFID chip.

In an embodiment, the identification chip of the first adapter cable and/or the identification chip of the second adapter cable includes read and write capabilities.

In an embodiment, the identification chip of the first adapter cable and/or the identification chip of the second adapter cable includes a memory component.

In an embodiment, the plurality of test pins are divided into a plurality of groups, wherein each group includes at least two test pins and at least one identification chip reader.

In an embodiment, the analyzer interface of the first adapter cable is configured to interface with at least two different groups simultaneously.

In an embodiment, the analyzer interface of the second adapter cable is configured to interface with only one group at a time.

In an embodiment, can further include a user interface electrically coupled to the analyzer, wherein the user interface is configured to display test results to a user.

In an embodiment, the analyzer interface of each adapter cable includes a locking mechanism to secure the adapter cable to the analyzer unit.

In an embodiment, each UUT interface is configured to connect to a different configuration of electrical wiring system.

In an embodiment, the processing element is configured to automatically calibrate the analyzer unit based on the identity of the connected adapter cables.

Various embodiments provide a testing system for evaluating electrical wiring systems. The system can include a storage unit, wherein the storage unit defines an interior volume, wherein the interior volume is configured to house one or more adapter cables, wherein the storage unit includes an identification chip reader, wherein the identification chip reader is configured to read and determine the identity of an identification chip, and a network interface, a first adapter cable, wherein the first adapter cable includes: an analyzer interface, a UUT interface, a central cable extending between and electrically coupling the analyzer interface with the UUT interface, and an identification chip coupled to the analyzer interface, the UUT interface, or the central cable, wherein the identification chip includes a unique identifier, a second adapter cable, wherein the second adapter cable includes: an analyzer interface, a UUT interface, a central cable extending between and electrically coupling the analyzer interface with the UUT interface, and an identification chip coupled to the analyzer interface, the UUT interface, or the central cable, wherein the identification chip includes a unique identifier, wherein the analyzer interface of the first adapter cable is structurally different than the analyzer interface of the second adapter cable, wherein the first adapter cable and the second adapter cable are disposed within the storage unit, wherein the identification chip reader of the storage unit requires physical contact of the identification chip reader with the identification chip.

In an embodiment, the interior volume of the storage unit is divided into a plurality of bays, wherein each bay includes an identification chip reader.

In an embodiment, the network interface of the storage unit is configured for communication with an external database.

Various embodiments provide a method for evaluating electrical wiring systems. The method can include connecting one or more adapter cables to an analyzer unit, determining the identity of the one or more adapter cables connected to the analyzer unit by reading a unique identification chip on each of the adapter cables with an identification chip reader of the analyzer, determining the location of the connection between the analyzer and each of the one or more adapter cables, modifying, creating, or obtaining a test procedure in accordance with the determined identities of and the locations of each of the one or more adapter cables, and running a test.

In an embodiment, the method can further include recording data in response to running the test, and displaying, on a user interface, at least a portion of the data that was recorded.

In an embodiment, the test results include diagnostic information that can identify specific failures within the electrical wiring system.

In an embodiment, the method can further include sending the recorded data to a remote server.

In an embodiment, the test procedure includes a test script. In an embodiment, modifying, creating, or obtaining a test procedure includes modifying or creating relay switching logic.

Various embodiments provide a method of managing adapter cables. The method can include receiving, at a system server, location data from an identification chip reader, wherein the location data includes the identification of an adapter cable and the identification of the chip reader, updating an adapter cable profile on a database with the received location data, receiving a request for the location of an adapter cable, retrieving location data from the database specific for the adapter cable, and displaying the location data on a user interface.

This summary is an overview of some of the teachings of the present application and is not intended to be an exclusive or exhaustive treatment of the present subject matter. Further details are found in the detailed description and appended claims. Other aspects will be apparent to persons skilled in the art upon reading and understanding the following detailed description and viewing the drawings that form a part thereof, each of which is not to be taken in a limiting sense. The scope herein is defined by the appended claims and their legal equivalents.

### BRIEF DESCRIPTION OF THE FIGURES

Aspects may be more completely understood in connection with the following figures (FIGS.), in which:

FIG. 1 is a perspective view of a testing system in accordance with various embodiments herein.

FIG. 2 is a schematic diagram of the unit under test in FIG. 1 in accordance with various embodiments herein.

FIG. 3 is a schematic diagram of a topology of a contract arrangement of the unit under test of FIG. 1 in accordance with various embodiments herein.

FIG. 4 is a perspective view of a stimulus and measurement device of the test system of FIG. 1 in accordance with various embodiments herein.

FIG. 5 is a schematic diagram depicting select components of the test system of FIG. 1 in accordance with various embodiments herein.

FIG. 6 is a schematic view of an analyzer connection end of an adapter cable in accordance with various embodiments herein.

FIG. 7 is a schematic view of an analyzer connection end of an adapter cable in accordance with various embodiments herein.

FIG. 8 is a schematic view of an analyzer connection end of an adapter cable in accordance with various embodiments herein.

FIG. 9 is a schematic view of an analyzer in accordance with various embodiments herein.

FIG. 10 is a schematic view of an analyzer with adapter cables connected in accordance with various embodiments herein.

FIG. 11 is a schematic view of an analyzer with adapter cables connected in accordance with various embodiments herein.

FIG. 12 is a schematic view of an analyzer with adapter cables connected in accordance with various embodiments herein.

FIG. 13 is a schematic view of a storage device in accordance with various embodiments herein.

FIG. 14 is a schematic view of an open storage device in accordance with various embodiments herein.

FIG. 15 is a schematic view of a facility in accordance with various embodiments herein.

FIG. 16 is a schematic view of various components of communicating over a network in accordance with various embodiments herein.

FIG. 17 is a flow chart depicting a method for testing a wire harness in accordance with various embodiments herein.

FIG. 18 is a flow chart depicting a method for monitoring an adapter cable in accordance with various embodiments herein.

FIG. 19 is a flow chart depicting a method for monitoring the location of an adapter cable in accordance with various embodiments herein.

While embodiments are susceptible to various modifications and alternative forms, specifics thereof have been shown by way of example and drawings, and will be described in detail. It should be understood, however, that the scope herein is not limited to the particular aspects described. On the contrary, the intention is to cover modifications, equivalents, and alternatives falling within the spirit and scope herein.

### DETAILED DESCRIPTION

In the manufacturing or installation of electrical wiring systems and harnesses, it is necessary to verify proper connectivity, the insulation resistance of the conductors, as well as other aspects of the electrical systems. Devices that run automated test scripts are well known. Such analyzers or automatic Test Equipment (ATE) require a plurality of interface adapters to connect to all conductors to be tested simultaneously, such that a test script can run automatically with little or no operator intervention after the test is started. To utilize the ATE, adapter cables are required to provide electrical connection between connectors on the ATE and connectors on the wiring harness being tested, Unit Under Test (UUT).

Due to the relative high cost of the ATE and the low volume of specific UUT configurations, ATEs are used to test a multitude of UUT configurations. In some cases, a unique set of adapter cables can be manufactured to match each unique configuration of the units under test. To switch from testing a UUT that is of a first version to UUT that is of a second version, all the first UUT adapter cables must be disconnected from the ATE and stored. The second UUT adapter cables could then be connected to the ATE. Previously, adapter cables must be connected to the ATE in very specific locations to ensure that the test program correctly tests the UUT. In large systems, connecting adapter cables may require several hours to successfully complete. All of the ATE side connectors of adapter cables can be similar, such that they are often installed incorrectly, leading to fault testing and time-consuming troubleshooting to determine the error. Additionally, since each UUT configuration requires a unique set of adapter cables, storage, maintenance and locating adapter cables is burdensome and leads to wasted time. For example, if a factory uses a 5000 point ATE system to test 200 different UUT configurations with 5000 points each, this factory must build and maintain 10,000 adapter cables (100 points/adapter cable×50 cables per configuration×200 configurations). In many cases, total cost of adapter cables can exceed the total cost of the ATE.

Various embodiments provided herein include adapter cables with an identification chip. The identification chip for each adapter cable can include a unique identification, such as a unique identification number, or a unique sequence of letters and numbers. The identification of an adapter cable can be determined through the detection of the identification chip. Once the identity of an adapter cable is known, various next steps can occur.

In some embodiments, once the identity of an adapter cable is known, a system can monitor its location, such as in storage or where it is connected to an analyzer. In some embodiments, the precise connection location of a known adapter cable can be determined, and a test script can be modified depending on the configuration of the adapter cables being connected to the analyzer.

Keeping track of the location of adapter cables can be problematic; however, the use of identification chips as provided herein can monitor a current location of a particular adapter cable or a last known location of a particular adapter cable. Other information can also be recorded with the use of an identification chip, such as the resistance of a specific adapter cable or the number of tests conducted using the specific adapter cable.

Adapter cables can have various lengths. In some embodiments, an adapter cable can be at least 3 ft long, 4 ft long, 5 ft long, 50 ft long, or 100 ft long. In various embodiments, an adapter cable or combination of adapter cables can be less than 300 feet long, less than 250 feet long, less than 200 feet long, or less than 150 feet long. In various embodiments, limiting the length of the adapter cables can increase the accuracy of the measurements by the analyzer. In various embodiments, increasing the length of the adapter cables can improve the usability of the system, such as by allowing technicians to more easily connect parts of the system without moving the analyzer 106.

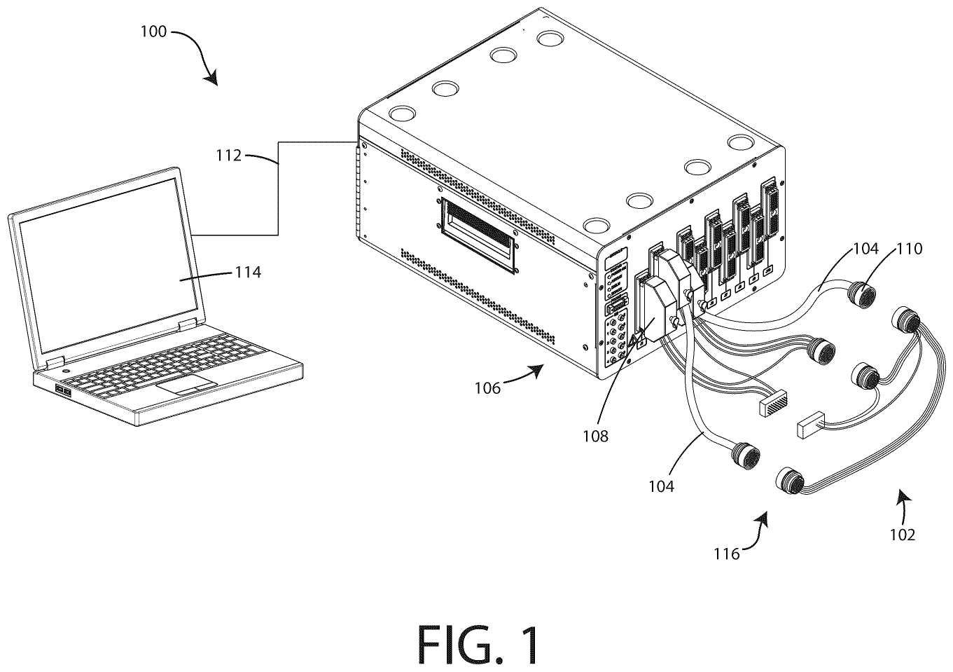

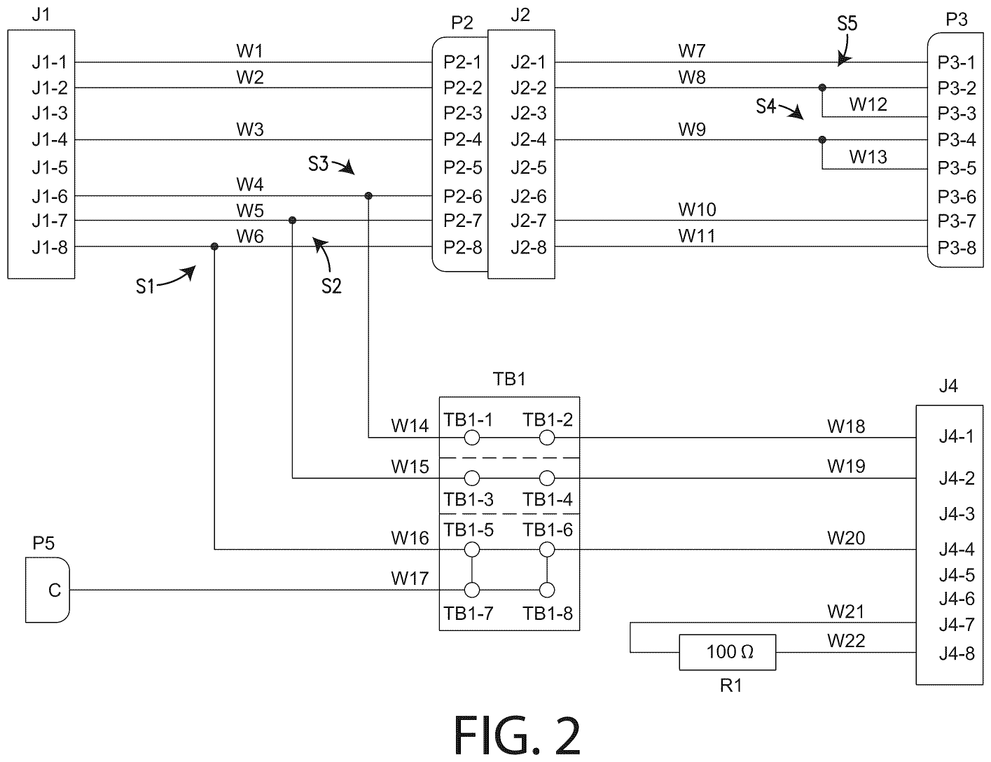

In reference now to FIG. 1, the testing system 100 according to various embodiments is shown. The system 100 may be provided for testing and analyzing an electrical wiring harness assembly 102. The electrical wiring harness assembly 102 may include one or more cables, connectors, switches, relays, resistors, diodes, or the like with one or more nodes, such as multi-node wire harnesses. A schematic of an example electrical wiring harness assembly 102 is depicted in FIG. 2.

The testing system 100 can include a plurality of adapter cables 104. Each adapter cable 104 can include an analyzer connector 108 for connecting the adapter cable 104 to a connector on the analyzer 106. The wire harness connector 110 can be configured to contact two or more pins of the electrical wiring harness 102, such as to create electrical communication.

The testing system 100 can include an analyzer 106, which can include a stimulus and measurement device. The analyzer 106 can be further configured to measure electrical characteristics of the electrical wiring harness assembly 102. The analyzer 106 is electrically connected to the wiring harness 102 via one or more adapter cables 104. The analyzer 106 can be configured to create a signal (e.g., output signal) for a wiring harness 102 being tested. The analyzer 106 can be configured to read or measure a return signal (e.g., input signal). The analyzer 106 can be configured to execute a test, such as an insulation test or a hipot test.

In various situations, the analyzer 106 can be configured to test a variety of different wire harnesses 102. Each wire harness can include different connections. As such, the adapter cables 104 can be configured with different wire harness connectors to electrically connect the analyzer 106 with the wire harness 102 being tested.

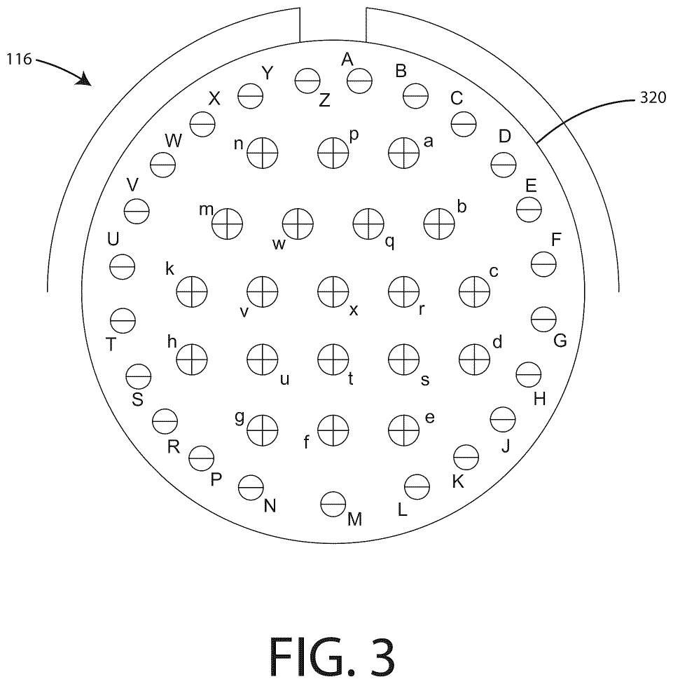

In reference now to FIG. 2, a schematic of an electrical wiring harness assembly 102 is shown in accordance with various embodiments. The electrical wiring harness assembly 102 can include connectors J1, J2, J4, P2, P3, P5, terminal block TB1, wires W1, W2, W3, W4, W5, W6, W7, W8, W9, W10, W11, W12, W13, W14, W15, W16, W17, W18, W19, W20, W21, W22, resistor R1, and splices S1, S2, S3, S4, S5 as shown in FIG. 2. The connectors J1, J2, J4, P2, P3 can each include a number of contacts: connector J1 includes contacts J1-1, J1-2, J1-3, J1-4, J1-5, J1-6, J1-7, and J1-8; connector P2 includes contacts P2-1 through P2-8; connector J2 includes contacts J2-1 through J2-8; etc. Connector P5 may include a “coax” connector, with a single center contact “C” and a shield connected to ground (not depicted). Terminal block TB1 can include a number of contacts TB1-1, TB1-2 . . . , TB1-8, and a number of internal interconnections TB1-1-2, TB1-3-4, TB1-5-6, TB1-5-7, TB1-6-8, TB1-7-8. The electrical wiring harness assembly 102 can include a harness or mating connector 116 for connecting to analyzer 106 via the adapter cable 104. An exemplary contact arrangement 320 for the harness is depicted in FIG. 3 with contacts A, B, C, D, E, F, G, H, J, K, L, M, N, P, R, S, T, U, V, W, X, Y, Z, a, b, c, d, e, f, g, h, k, m, n, p, q, r, s, t, u, v, w, x.

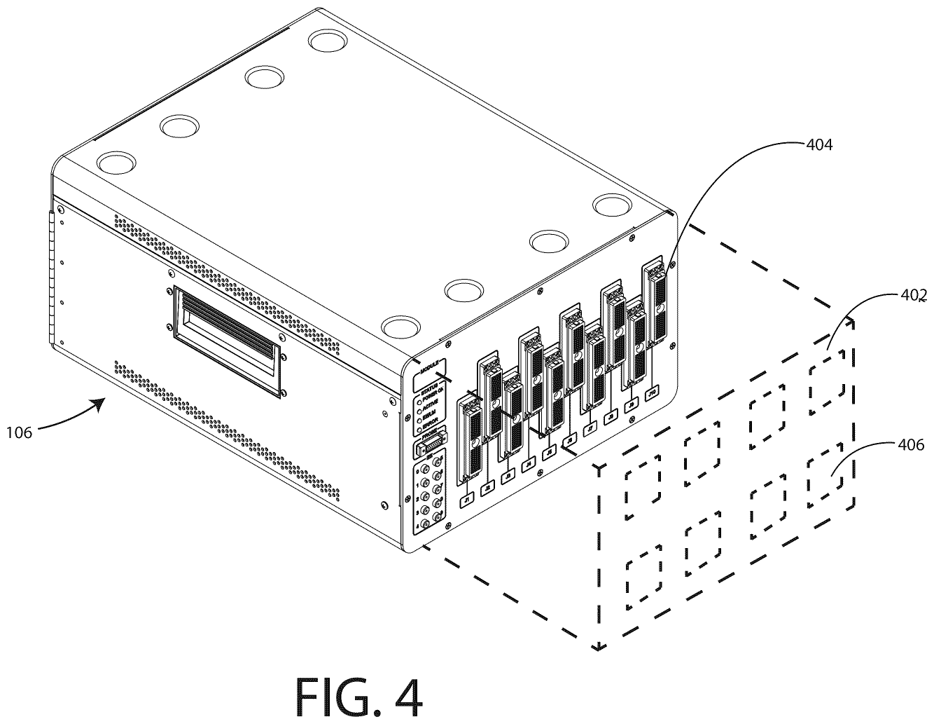

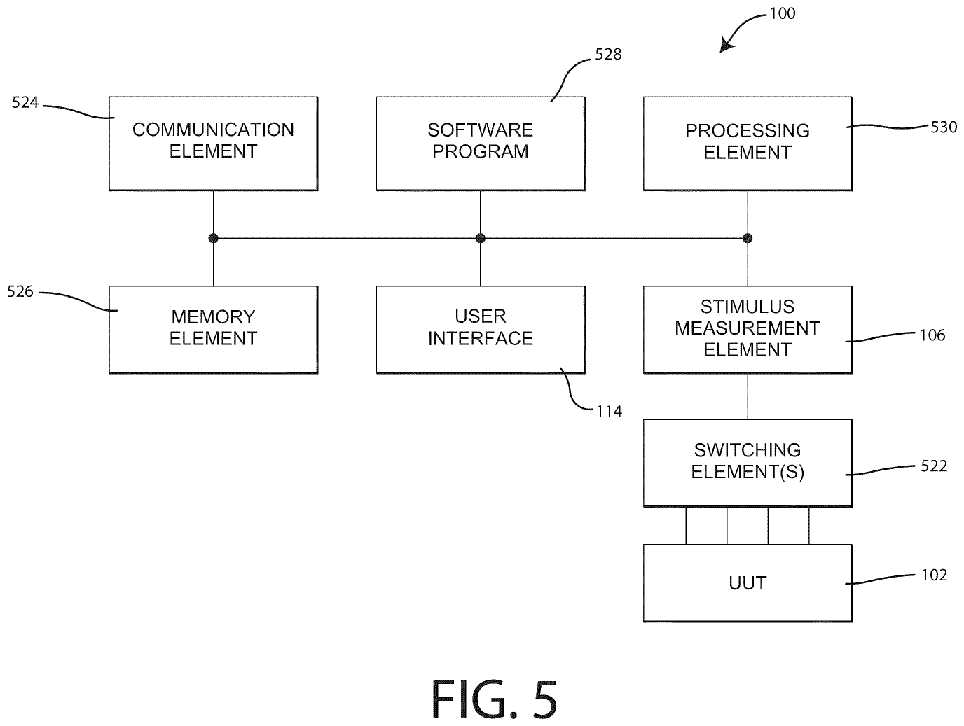

Turning to FIGS. 4 and 5, the system 100 broadly comprises one or more adapter cables 104, an analyzer 106, a switching element 522 (shown in FIG. 5), a user interface 114, a communication element 524, a memory element 526, a software program 528, and a processing element 530. The adapter cable 104 is configured to connect to the wire harness 102 through the wire harness connector 110 of the adapter cable 104 mating with the connector 116 of the electrical wiring harness assembly 102.

The analyzer 106 is configured to generate a signal for performing tests on the electrical wiring harness assembly 102. The analyzer 106 may be configured to generate a voltage, current, waveform, or the like, and measure various electrical properties of the electrical wiring harness assembly 102 in response to the stimuli. The switching element 522 is configured to connect the analyzer 106 to the wire harness interface 102. The switching element 522 may comprise a switching matrix, such as a switch module, or pluralities thereof. In some embodiments, the switching element 522 may be integrated into the analyzer 106. In some embodiments, the switching element 522 may comprise a switch module connected to the analyzer 106 and/or the adapter cables 104.

The user interface 114 generally allows the user to utilize inputs and outputs to interact with the system 100. The user interface 114 may be in communication with the analyzer 106 via a wired and/or wireless connection, as schematically represented by line 112 in FIG. 1. The wired or wireless connection 112 may comprise an ethernet cable, a USB cable, a Wi-Fi connection, a Bluetooth™M connection, or any of the communication techniques described below in connection with the communication element 524. Inputs may include buttons, pushbuttons, knobs, jog dials, shuttle dials, directional pads, multidirectional buttons, switches, keypads, keyboards, mice, joysticks, microphones, touch screens, mouse pads, or the like, or combinations thereof. Outputs may include audio speakers, lights, dials, meters, printers, screens, displays, or the like, or combinations thereof. With the user interface 114, the user may be able to control the features and operation of what is displayed. While FIG. 1 depicts the testing system 100 as comprising various components integrated in separate housings, the components of the testing system 100 may be integrated and/or connected in any number of ways without departing from the scope of the present invention. For example, in some embodiments, all the components of the system 100 may be integrated into a single device with a single housing.

The communication element 524 generally allows communication between the system 100 and other testing systems, external devices, laptops, computers, or the like. The communication element 524 may include signal or data transmitting and receiving circuits, such as antennas, amplifiers, filters, mixers, oscillators, digital signal processors (DSPs), and the like. The communication element 524 may establish communication wirelessly by utilizing radio frequency (RF) signals and/or data that comply with communication standards such as cellular 2G, 3G, 4G or 5G, Institute of Electrical and Electronics Engineers (IEEE) 802.11 standard such as WiFi, IEEE 802.16 standard such as WiMAX, Bluetooth™, or combinations thereof. In addition, the communication element 524 may utilize communication standards such as ANT, ANT+, Bluetooth™ low energy (BLE), the industrial, scientific, and medical (ISM) band at 2.4 gigahertz (GHz), or the like. Alternatively, or in addition, the communication element 524 may establish communication through connectors or couplers that receive metal conductor wires or cables, like Cat 6 or coax cable, which are compatible with networking technologies such as ethernet. In certain embodiments, the communication element 524 may also couple with optical fiber cables. The communication element 524 may be in communication with the user interface 114, the memory element 526, and/or the processing element 530.

The memory element 526 may include electronic hardware data storage components such as read-only memory (ROM), programmable ROM, erasable programmable ROM, random-access memory (RAM) such as static RAM (SRAM) or dynamic RAM (DRAM), cache memory, hard disks, floppy disks, optical disks, flash memory, thumb drives, universal serial bus (USB) drives, or the like, or combinations thereof. In some embodiments, the memory element 526 may be embedded in, or packaged in the same package as, the processing element 530. The memory element 526 may include, or may constitute, a “computer-readable medium.” The memory element 526 may store the instructions, code, code segments, software, firmware, programs, applications, apps, services, daemons, or the like that are executed by the processing element 530. In an embodiment, the memory element 526 stores the software application/program 528. The memory element 526 may also store settings, data, documents, sound files, photographs, movies, images, databases, and the like.

The processing element 530 may include electronic hardware components such as processors. The processing element 530 may include microprocessors (single-core and multi-core), microcontrollers, digital signal processors (DSPs), field-programmable gate arrays (FPGAs), analog and/or digital application-specific integrated circuits (ASICs), or the like, or combinations thereof. The processing element 530 may generally execute, process, or run instructions, code, code segments, software, firmware, programs, applications, apps, processes, services, daemons, or the like. For instance, the processing element 530 may execute the software application/program 528. The processing element 530 may also include hardware components such as finite-state machines, sequential and combinational logic, and other electronic circuits that can perform the functions necessary for the operation of the current invention. The processing element 530 may be in communication with the other electronic components through serial or parallel links that include universal busses, address busses, data busses, control lines, and the like.

The processing element 530 is configured to perform one or more tests on the electrical wiring harness assembly 102 via the switching element 522 and the adapter cable(s) 104, analyze the results, and output the results in various forms, such as in natural language via the user interface 114 or recording of results in a log in the memory element 526. For example, the processing element 530 may be configured to determine prospective insulation leakage errors between networks that should be isolated from each other in the electrical wiring harness assembly 102. For each error, the processing element 530 may be configured to access a database of wiring diagrams and display a wiring diagram for one or more networks that have been determined have an error associated with them. The processing element 530 may be configured to report probable error type in natural language via the user interface 114. The reporting may comprise displaying the natural language on a display of the user interface 114, printing the natural language via a paper printer of the user interface 114, outputting the natural language to a data file, or the like. In response to determining an error exists, a user can be notified of the error and then fix the error.

Various embodiments can include a faceplate 402 connected to the analyzer 106. The faceplate 402 can include a plurality of connections 406. The connections 406 can be configured to be connected to the analyzer interface of an adapter cable. FIG. 4 shows an example of a faceplate 402 connected to analyzer 106. In some embodiments, a user can design, build, and connect a faceplate 402 to an analyzer 106. A faceplate 402 can allow a user connect adapter cables, such as an old set or previously used set of adapter cables, to an analyzer that includes connections that would otherwise not connect with the analyzer interface of the adapter cables. In some embodiments, the faceplate 402 can function as an adapter for the adapter cable to connect to the analyzer 106.

In some embodiments, a faceplate 402 can be disposed between the analyzer 106 and the analyzer interface of an adapter cable. In various embodiments, the faceplate 402 can include one or more connections 406 for connecting to an adapter cable. The number of connections 406 on a faceplate 404 can differ from the number of connections 406 that are available on the analyzer 106. While the disclosure may at times reference connecting an adapter cable to an analyzer 106, it should be understood that the adapter cable can be directly connected to the analyzer in some scenarios and connected to a faceplate 402 in other scenarios. In some embodiments, the faceplate 404 can include one or more identification chip readers described herein.

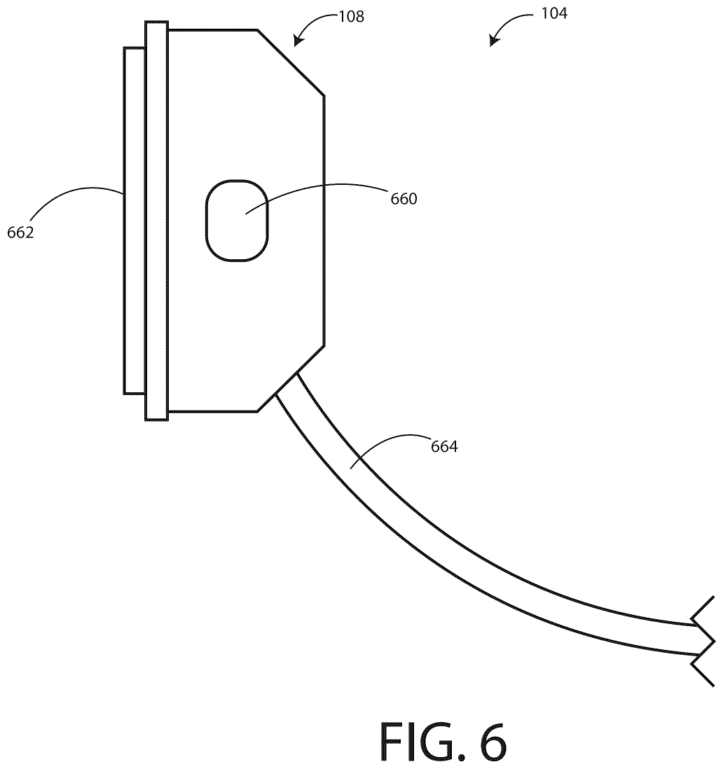

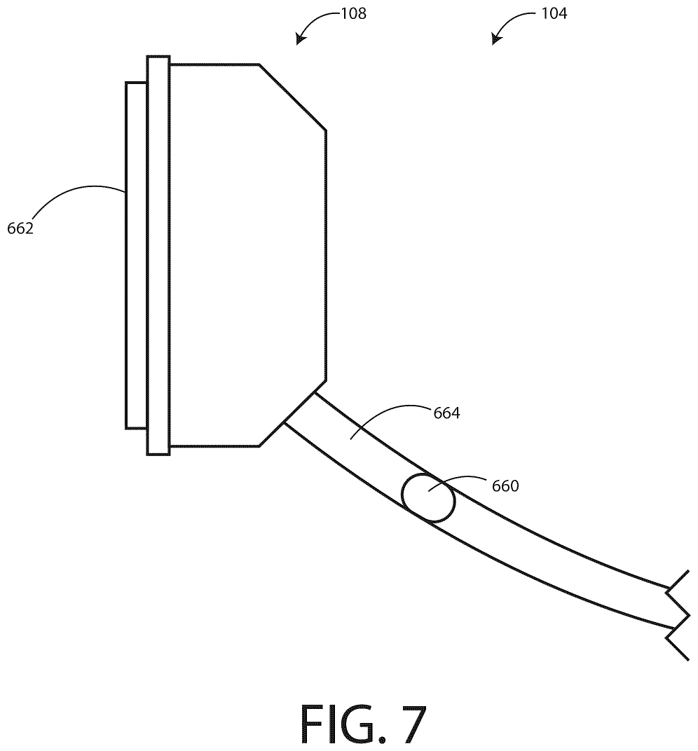

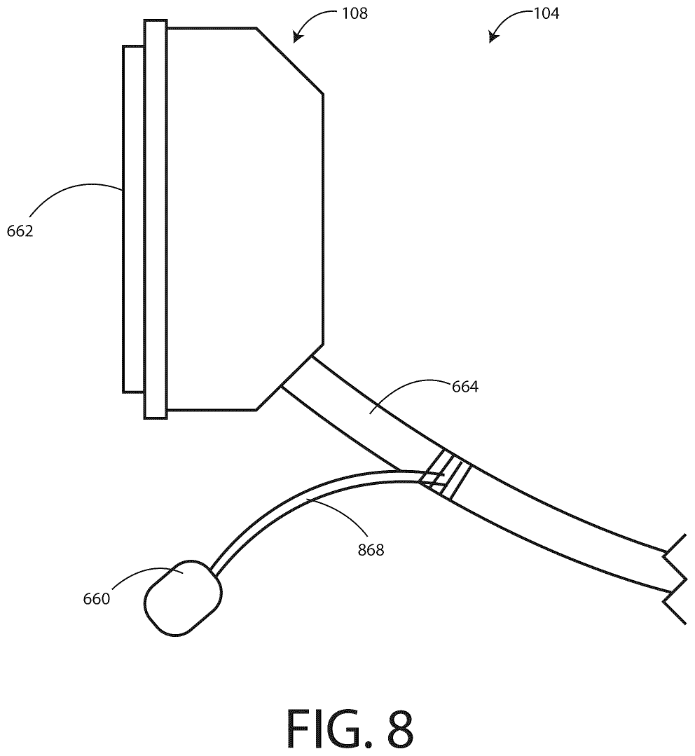

FIGS. 6-8 show various embodiments of analyzer cables 104 that include an identification chip 660 in accordance with various embodiments herein. FIG. 6 shows a schematic view of an adapter cable 104 including an identification chip 660 disposed within the analyzer connector 108. FIG. 7 shows a schematic view of an adapter cable 104 including an identification chip 660 disposed within the central cable 664 connecting the analyzer connector 108 to the wire harness connector 110. FIG. 8 shows a schematic view of an adapter cable 104 including an identification chip 660 disposed on an extension 868.

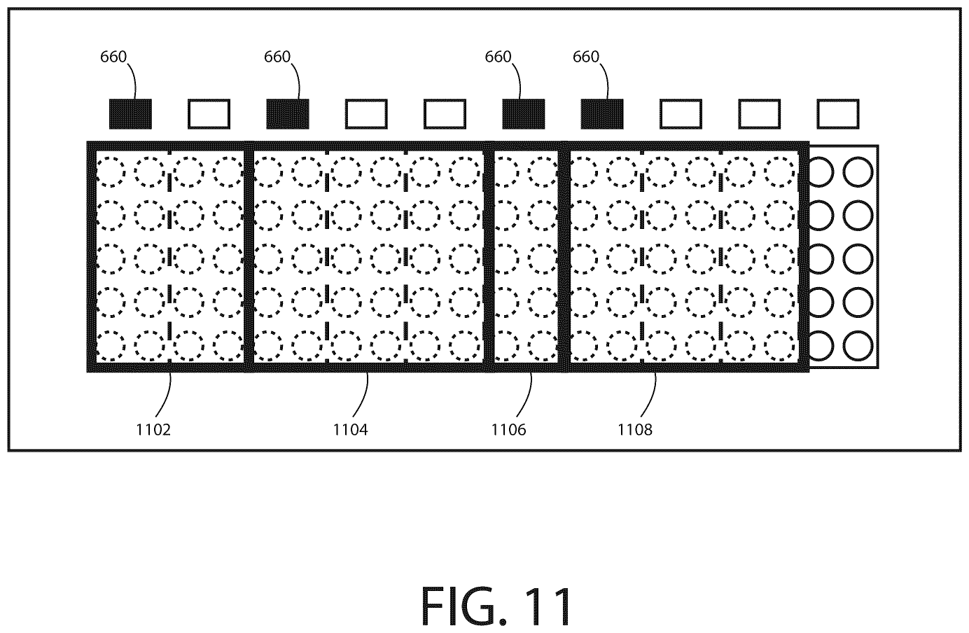

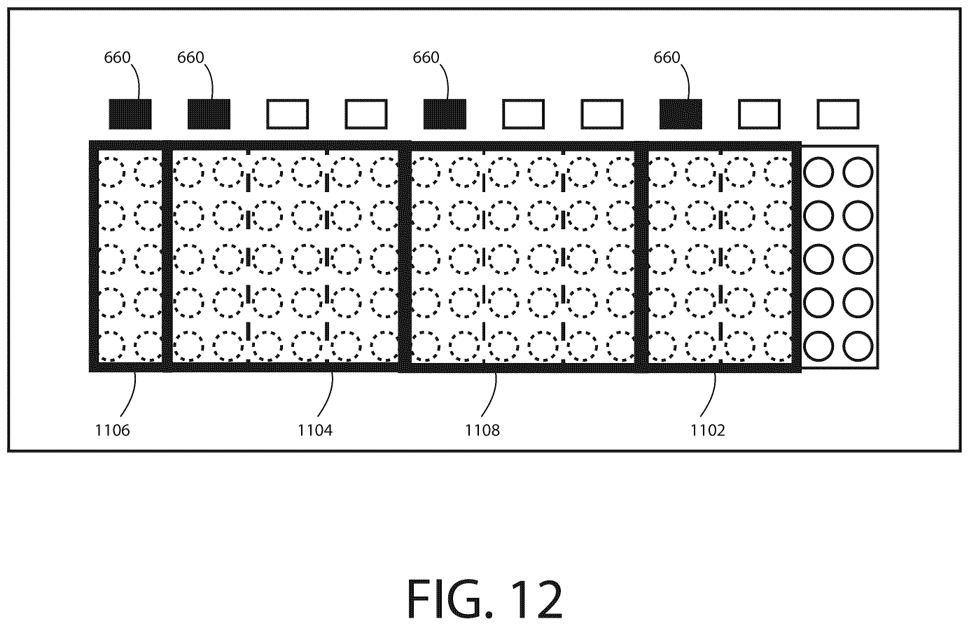

An analyzer connector 108 can include an analyzer interface 662, such as a portion of the analyzer connector 108 that interfaces or contacts the analyzer 106. The analyzer interface 662 can vary between different adapter cables. As an example and shown in FIGS. 11-12, some analyzer interfaces 662 may include 10 points while other analyzer interfaces 662 may include 30 points. In various embodiments, an analyzer interface 662 can include at least 4 points and less than 100 points. In various embodiments, the analyzer interface 662 is configured to connect with a plurality of the test points 942.

The adapter cable 104 can include an analyzer connector 108 and a wire harness connector 110 disposed on either end of a central cable 664. The central cable 664 can include a mesh covering the outside surface. The central cable 664 can electrically couple the analyzer connector 108 with the wire harness connector 110. In various embodiments, the analyzer connector 108 can vary between different adapter cables, such as having a different number of connection pins and/or a different configuration of the connection pins. In various embodiments, the wire harness connector 110 can vary between different adapter cables, such as having a different number of connection pins and/or a different configuration of the connection pins.

As shown in FIG. 8, in some embodiments, the adapter cable 104 can include an extension 868, which can allow the identification chip 660 to move relative to the remainder of the adapter cable 104. In some embodiments, preexisting adapter cables 104 can be retro fit with an identification chip 660, such as by attaching an extension 868 including an identification chip 660 to an adapter cable. In some embodiments, the extension 868 can be coupled to the adapter cable via a connector, such as metal tape.

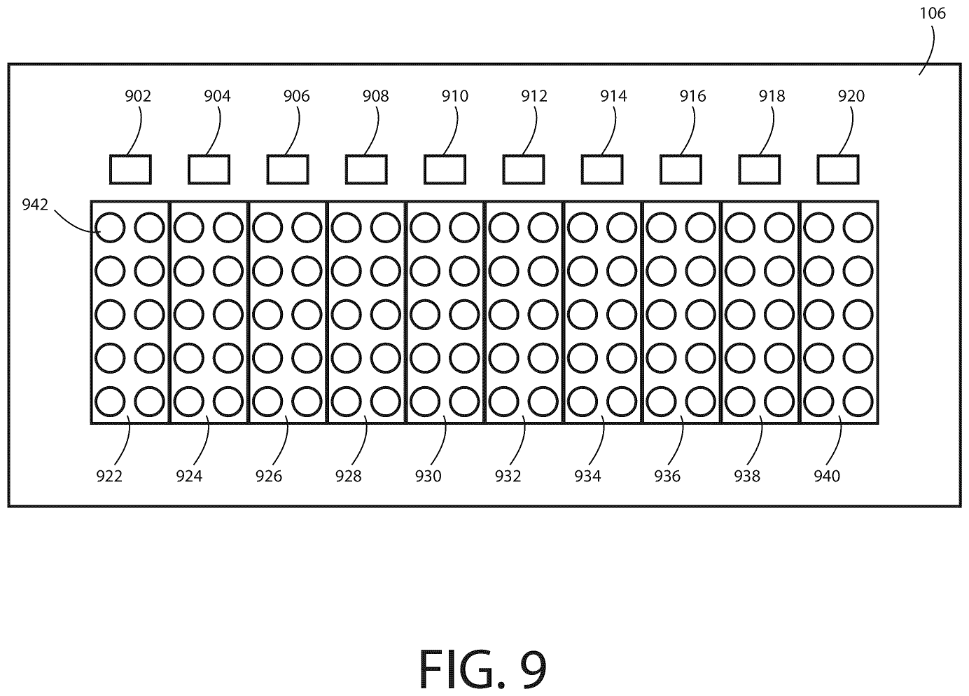

FIG. 9 is a schematic view of an analyzer 106 in accordance with various embodiments herein. In various embodiments, an analyzer 106 can include a plurality of chip readers 902, 904, 906, 908, 910, 912, 914, 916, 918, 920. A chip reader can be configured to accept or read an identification chip 660. In various embodiments, the chip reader can include a magnetic connection. In various embodiments, the chip reader can require the magnetic connection to identify the identification chip. In some embodiments, a physical connection between the identification chip and the chip reader can be required, such as to create a circuit to allow the chip to be read. In some embodiments, a physical connection or electrical connection must be made between the identification chip and the chip reader, such that a wireless signal would not be sufficient. In such embodiments, current locations of identification chips (and their associated adapter cables) can be determined, as opposed to a last known location of the identification chip. If the identification chip is current physically in contact with the chip reader, the system will know the identification chip's current location. In various embodiments, prior to running a test, the analyzer 106 can determine the identity of and the location of each adapter cable 104 that is coupled to the analyzer 106 by reading the identification chip 660 with a chip reader. The analyzer 106 can then revise a test script to accommodate the known adapter cables in the known locations.

In various embodiments, an analyzer 106 can include a plurality of groups or sections 922, 924, 926, 928, 930, 932, 934, 936, 938, 940 of points 942. In various embodiments, each group 922, 924, 926, 928, 930, 932, 934, 936, 938, 940 can include a chip reader 902, 904, 906, 908, 910, 912, 914, 916, 918, 920. The use of the identification chip 660 can result in not needing one or more, such as two, point connections 942 to identify an adapter cable, which can result in more points 942 being available for testing purposes as opposed to identification purposes. In various embodiments, the chip reader can be structurally different from the points. In such embodiments, the points 942 would not be capable of connecting with the identification chip of an adapter cable.

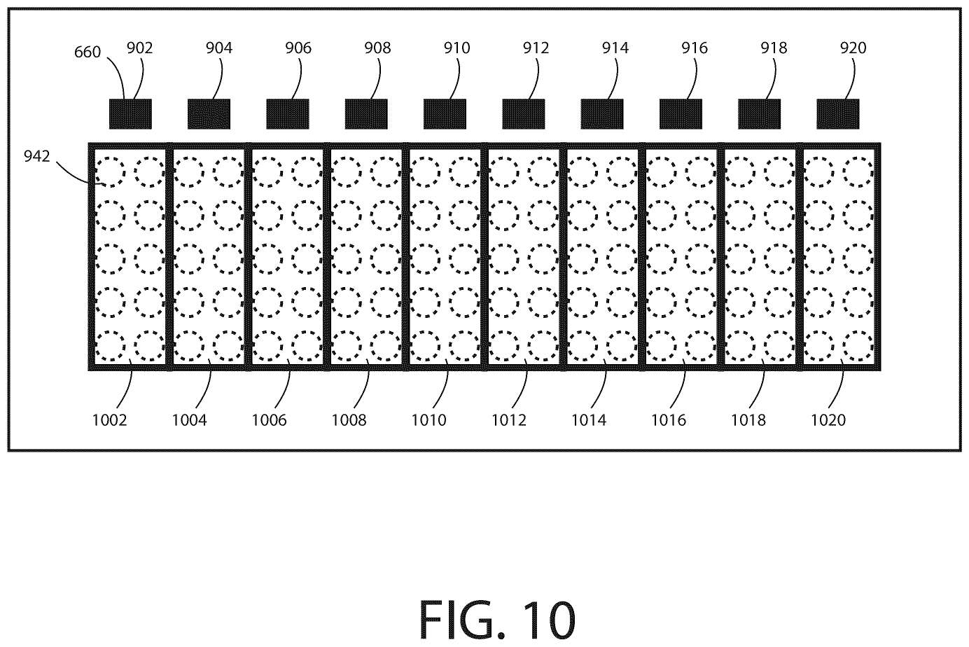

FIG. 10 shows a schematic view of an analyzer 106 with adapter cables connected in accordance with various embodiments herein. In FIG. 10 all of the pin connections 942 are coupled to one of the adapter cables.

FIG. 10 shows ten adapter cables 1002, 1004, 1006, 1008, 1010, 1012, 1014, 1016, 1018, 1020 being coupled to the analyzer 106. The analyzer 106 can know the identity of and the location of each adapter cable based on the corresponding identification chips 660 being read by the chip readers 902, 904, 906, 908, 910, 912, 914, 916, 918, 920. While the analyzer connectors of the adapter cables 1002, 1004, 1006, 1008, 1010, 1012, 1014, 1016, 1018, 1020 are all the same in FIG. 10, the wire harness connectors of each adapter cable 1002, 1004, 1006, 1008, 1010, 1012, 1014, 1016, 1018, 1020 can be different, such that the analyzer 106 needs to (and does) know the identify of each adapter cable.

FIG. 11 shows a schematic view of adapter cables 1102, 1104, 1106, 1108 connected to the analyzer 106 in accordance with various embodiments herein. FIG. 12 shows a schematic view of adapter cables 1102, 1104, 1106, 1108 connected to the analyzer 106 in a different arrangement than in FIG. 11 in accordance with various embodiments herein.

FIGS. 11 and 12 show one advantage of some of the embodiments described herein. The setup in preparation for running a test can generally be a very time consuming and labor-intensive process, because the adapter cables would need to be connected in specific locations to align with the preprogramed test script. In contrast and as shown in FIGS. 11 and 12, the adapter cables can be connected in random location, since the location and identity of an adapter cable can be known through reading the associated identification chip.

FIGS. 11 and 12 further show that different adapter cables 1102, 1104, 1106, 1108 can include different physical configurations of the connection interfaces. As an example, adapter cable 1102 includes an interface for 20 connection points, adapter cables 1104, 1108 include an interface for 30 connection points, and adapter cable 1106 includes an interface for 10 connection points.

### Storage

Once a test has been completed, the adapter cables can be disconnected and stored. Additionally, prior to a test, adapter cables can be organized and stored for future use. The identification chip 660 in each adapter cable can make the storage and retrieval process less labor intensive and more efficient. The identification chip 660 can allow for smart containers with an interface (i.e. chip reader) for an identification chip to be plugged into. The smart container can be connected to a network with other smart containers to accurately know the location of each adapter cable that a user has.

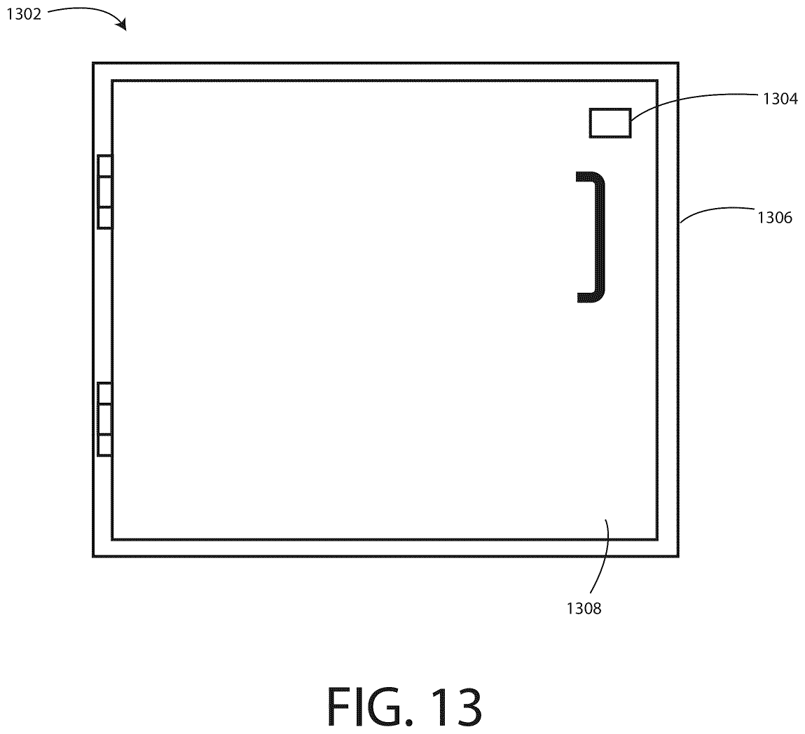

FIG. 13 shows a schematic view of a storage device 1302 in accordance with various embodiments herein. In various embodiments, the storage device 1302 can include a chip reader 1304 similar to other chip readers described herein. Prior to placing an adapter cable into the storage device 1302, the chip reader 1304 can read an identification chip of an adapter cable to establish a known location of the adapter cable. In some embodiments, the chip reader 1304 can be disposed on the exterior 1306 of the storage device 1302, such as on a cover, a lid, or a door 1308.

In some embodiments, the storage device can determine the identification of an adapter cable by reading an identification chip. If the adapter cable is intended to be stored in a different storage device, a user interface can provide a message to a user or the cover, lid or door 1308 can remain locked or otherwise closed to prevent an adapter cable from being stored in the incorrect location.

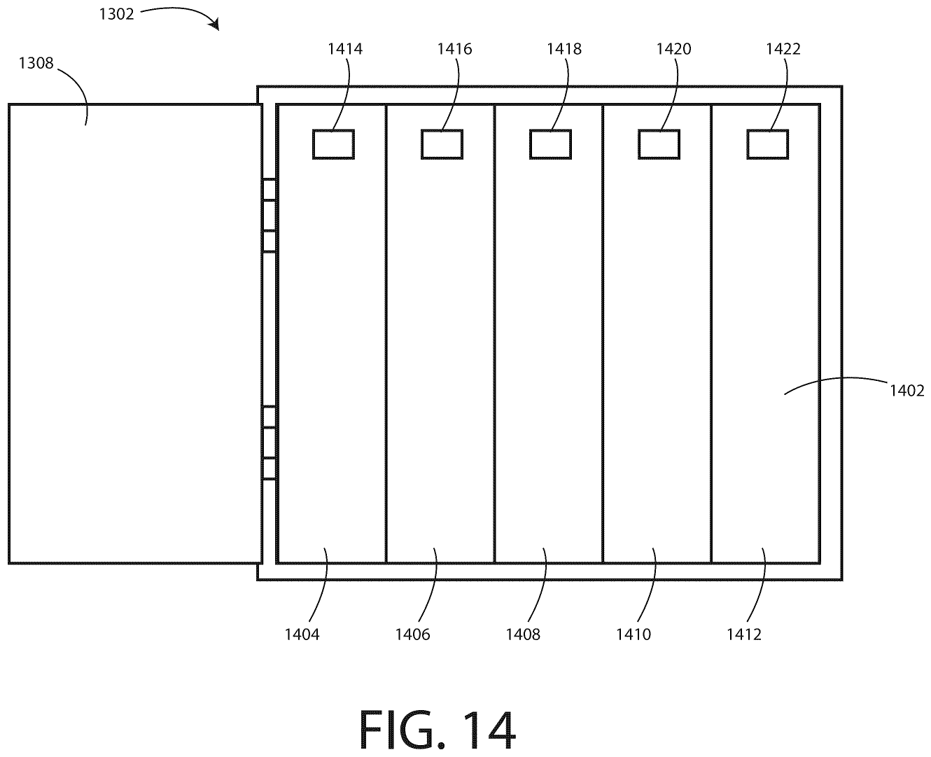

FIG. 14 shows a schematic view of the interior 1402 of the storage device 1302 in accordance with various embodiments herein. In various embodiments, the storage device 1302 can be configured to house multiple adapter cables. In various embodiments, the interior 1402 of the storage device 1302 can include multiple bays or compartments 1404, 1406, 1408, 1410, 1412. Each bay or compartment 1404, 1406, 1408, 1410, 1412 can be configured to house one adapter cable.

In some embodiments, each bay or compartment 1404, 1406, 1408, 1410, 1412 can include a chip reader 1414, 1416, 1418, 1420, 1422. In some embodiments, an adapter cable stored in a bay 1404, 1406, 1408, 1410, 1412 can have its identification chip plugged into, connected to, or read by the respective chip reader 1414, 1416, 1418, 1420, 1422. Providing a chip reader for each adapter cable that is stored in the storage device 1302 can allow real-time monitoring of the location of the specific adapter cables. As such, the time required to locate a desired adapter cable can be greatly reduced.

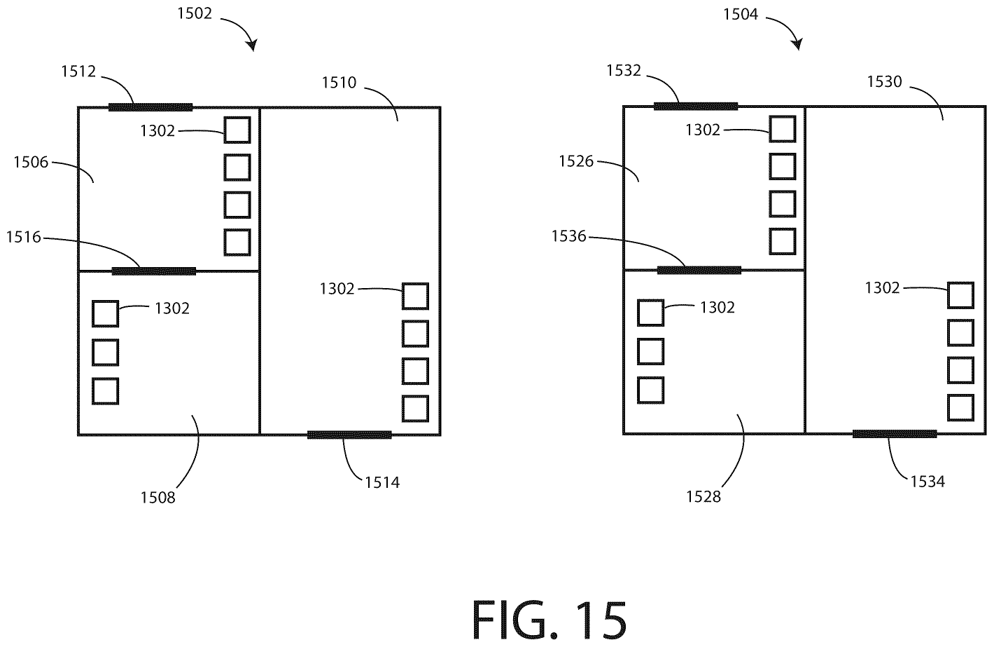

FIG. 15 shows a schematic of a facility. The facility can include multiple buildings, such as a first building 1502 and a second building 1504. A first building 1502 can include multiple rooms, such as a first room 1506, a second room 1508, and a third room 1510. The first building 1502 can include one or more exterior doors 1512, 1514 and one or more internal doors 1516. In various embodiments, one or more storage devices 1302 can be disposed within one or more of the rooms 1506, 1508, 1510. In some embodiments, different types of chip readers can be used at different points in a system. As an example, a wireless chip reader can be used at one or more places in a system, such as different entry points (i.e., doors) to rooms or buildings. Whereas, a chip reader that requires a physical connection can be used at the storage devices and/or the analyzers. In some embodiments, a single adapter cable can include two identifications chips. The two identification chips can be different, such as one being a wireless chip and one requiring a physical connection.

Similar to the first building, a second building 1504 can include multiple rooms, such as a first room 1526, a second room 1528, and a third room 1530. The second building 1504 can include one or more exterior doors 1532, 1534 and one or more internal doors 1536. In various embodiments, one or more storage devices 1302 can be disposed within one or more of the rooms 1526, 1528, 1530.

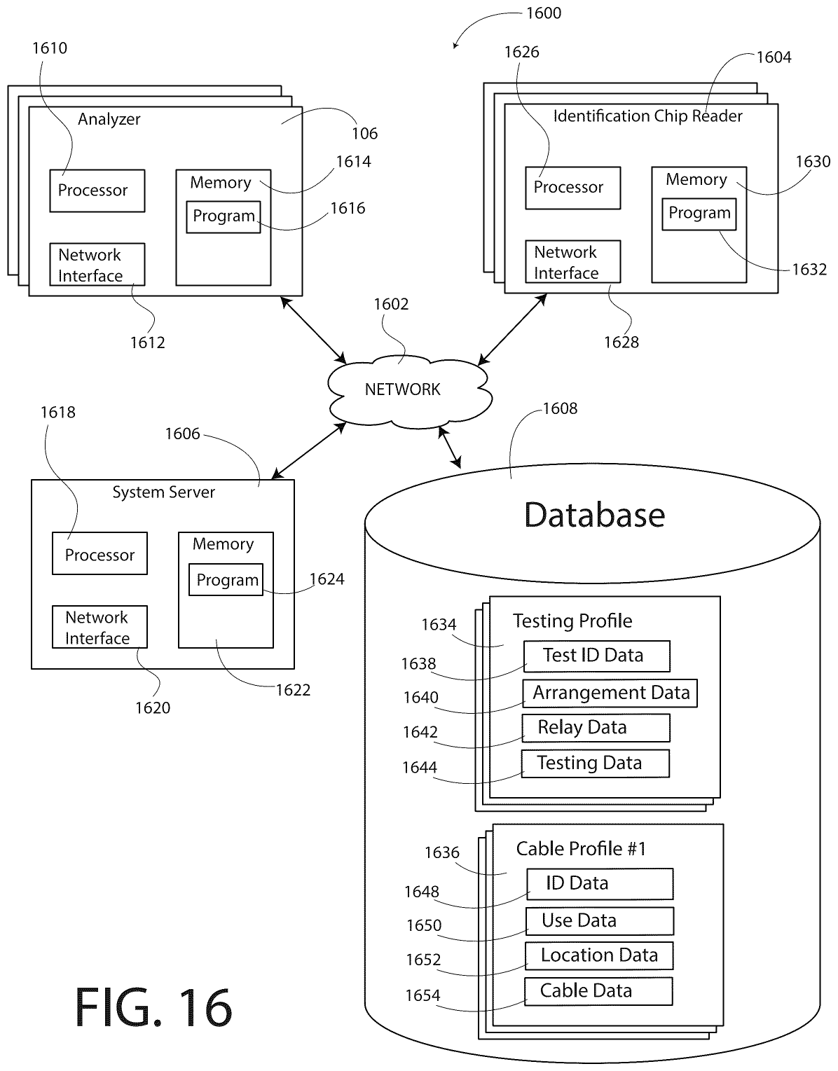

The stored data, such as discussed in FIG. 16, can include location data for each of the adapter cables. The location data can include building data, such as a building that an adapter cable was last known to be located within. The location data can include room data, such as a room that an adapter cable was last known to be located within. The location data can include storage device data, such as a storage device that an adapter cable was last known to be located within. The location data can include bay data, such as a bay that an adapter cable was last known to be located within.

In various embodiments, each building can include an identification chip reader, such as at each of the exterior doors. The system can be configured to track which adapter cables are in the building and which adapter cables have left the building. In some embodiments, the identification chip readers can determine when an identification chip has passed by the identification chip reader, such as when a person carries an adapter cable through a doorway

In various embodiments, each room within a building can include an identification chip reader, such as at an interior door or exterior door. The system can be configured to track which adapter cables are in which room of a building. Similarly, the tracking of an adapter cables location can be more specific than a room in a building. The tracking can also include which storage device and/or bay each adapter cable is stored in.

The location data can include a history of known locations, such as a log of when the identification chip has been identified by an identification chip reader. As an example, cable #2934 entered building #3, door #2 at 08:56 on Sep. 2, 2024. Further, the location data can include current location data, such as if an identification chip is currently being read or detected by an identification chip reader. As an example, a cable can be stored in a storage device 1302, such as shown in FIGS. 13-14. The current location data can include an up-to-date status of the identification chip. In some embodiments, the current location data can include building data, room data, storage device data, and bay data. In some embodiments, the current location data can include a current status, such as being read/identified or not currently being read/identified. An identification chip can be currently being read/identified when it is in contact with an identification chip reader.

### Network

The system 1600 shown in FIG. 16 can include one or more analyzers 106, one or more identification chip readers 1604, and one or more system servers 1606. It should be understood that each of these elements can include one or more computer systems or be connected to one or more computer systems, such as to allow the elements to communicate (i.e., send and receive data) over a network 1602. It should be understood that the system server 1606 can also represent other standard computing systems that are able to send and receive data across networks 1602 as part of system 1600. Similarly, an identification chip reader 1604 can include a standard computing system that is associated with a particular chip reader to send and receive data across networks 1602 as part of system 1600. In some embodiments, a single standard computing system can be electrically connected to multiple identification chip readers and the single standard computing system can provide network access for a plurality of identification chip readers.

In various embodiments, these computing systems can each include a processor 1610, 1618, 1626, memory and/or storage 1614, 1622, 1630 and a network interface 1612, 1620, 1628 to allow communications over network 1602. The memory 1614, 1622, 1630 is shown in FIG. 16 as including programming 1616, 1624, 1632 that can control the processors 1610, 1618, 1626. It should be understood that other devices that include computing systems can also include similar elements, such as a processor, network interface, memory, and computer programming.

In some embodiments, the analyzer 106, the system server 1606, and an identification chip reader 1604 can take the form of or include a standard computer system. The devices 106, 1604, 1606 can be implemented using a plurality of separate, individual computers in some embodiments.

A standard computer system can operate application software or browser software, such as programs 1616, 1624, 1632, which can be stored in memory 1614, 1622, 1630 on the respective devices. The programs can allow the devices to communicate over the network 1602 as part of the system 1600.

In various embodiments, the system server 1606 receives data from the analyzer, such as use data or cable data, and/or from an identification chip reader 1604, such as location data. The system server 1606 can store the data in database 1608. In various embodiments, the system server 1606 receives data from an identification chip reader 1604 in the form of location data. The location data can be saved in the database 1608.

The system server 1606 can be in communication with a plurality of other analyzers 106 and/or identification chip readers 1604 and may aggregate all their data in a single database 1608. In other embodiments, data from separate chip readers 1604 or analyzers 106 can remain separated into separate databases that are still accessible to the system server 1606.

The computer of devices 106, 1604, 1606 can be a computing device that includes a processor for processing computer programming instructions. In most cases, the processor can be a CPU. Various different CPU devices are possible, such as those created by Intel Corporation (Santa Clara, California), Advanced Micro Devices, Inc (Santa Clara, California), or a RISC processer produced according to the designs of Arm Holdings PLC (Cambridge, England). Additionally, the computers can include memory. The memory can be in the form of both temporary, random access memory (RAM) and more permanent storage such a magnetic disk storage, FLASH memory, or another non-transitory (also referred to as permanent) storage medium. The memory and storage, which can be referred to collectively as “memory”, can contain both programming instructions and data. In various embodiments, both programming and data can be stored permanently on non-transitory storage devices and transferred into RAM when needed, such as for processing or analysis. In some embodiments, the computers can include a graphics processing unit (or GPU) for processing of visual input and outputs.

In various embodiments, the various data can be stored locally and/or stored remotely. In FIG. 16, the data can be stored in database 1608. In many embodiments, the database 1608 can be a portion of the system server 1606. In other embodiments, the database 1608 can be a separate element from the system server 1606. In some embodiments, the database 1606 can consist of local storage on the various devices included in the system 1600.

In various embodiments, database 1608 can be a single database on a single storage medium or be made up of multiple storage mediums. The database 1608 can include data related to the tracking of adapter cables for retrieval, tracking of adapter cables for testing purposes, and/or specifics for adapter cables to increase accuracy of a test. In various embodiments, the testing profile or cable profile can include a log, such as a list of testing events or location events that have occurred. The log can be updated upon receiving new data, such as new location data for a given adapter cable.

Database 1608 can include a plurality of testing profiles 1634, such as one profile 1634 for each test that an analyzer can potentially execute. Each testing profile 1634 can include test ID data 1638, such as an identification number or other data specific to the testing profile 1634. The test ID data 1638 can provide a way to easily access and identify a specific testing profile 1634.

In various embodiments, each testing profile 1634 can include arrangement data 1640. Arrangement data 1640 can include data related to the way in which the analyzer 106, adapter cables, and a UUT should be configured for the test script to be run properly. Examples of arrangement data 1640 can include which pins or points should be sent which signals in a test script. The arrangement data 1640 can include data related to the expected arrangement of adapter cables and connections with the analyzer. In some embodiments, upon learning the locations of where each adapter cable is connected to the analyzer, the test script or arrangement data can be modified to account for differences between a stored (i.e., expected) configuration and an actual configuration of the adapter cables and the analyzer.

In various embodiments, each testing profile 1634 can include relay data 1642. In some embodiments, a plurality of relays can be used to account for differences between the arrangement data and the location data (i.e., current configuration of the adapter cables and the analyzer). The relays can be controlled by a switching logic procedure to ensure the correct signals are sent to the correct connection points. In such embodiments, in contrast to changing a test script, a switching relay logic procedure can be modified or created to account for the current configuration of the adapter cables and the analyzer.

In various embodiments, each testing profile 1634 can include testing data 1644. Testing data 1644 can include data related to a test, such as a test script. The testing data 1644 can include information related to a test to be conducted. The testing data 1644 can include data related to what signals should be sent, the strength and/or frequency of sent signals, and other information that the system needs to conduct the tests on the UUT with the analyzer.

Database 1608 can include a plurality of cable profiles 1636, such as one profile 1636 for each adapter cable of a system. Each cable profile 1636 can include ID data 1648, such as an identification number or other data used to identify a specific adapter cable. The ID data 1648 can provide a way to easily access data regarding, and identify, a specific cable profile 1636.

In various embodiments, each cable profile 1636 can include use data 1650. Use data 1650 can include historical use data of the cable. The use data 1650 can include data related to the number of times the cable has been used and/or historical log of the times the cable has been used.

In various embodiments, each cable profile 1636 can include location data 1652. The location data 1652 can include a log of location data, such as a list of all of the known locations the cable has been. Each time the identification chip of the cable is identified by a card reader a new event can be logged. In some embodiments, the location data 1652 can include current status data, such as whether or not the identification chip is currently being read by a chip reader or not. In some embodiments, the location data 1652 can include building data, such as the last known building the adapter cable was located in, evidenced by the identification chip being read by a chip reader in the building or associated with the building.

In some embodiments, the location data 1652 can include room data, such as the last known room of a building the adapter cable was located in, evidenced by the identification chip being read by a chip reader in the room or associated with the room.

In some embodiments, the location data 1652 can include storage unit or device data, such as the last known storage device the adapter cable was located in, evidenced by the identification chip being read by a chip reader in the storage device or associated with the storage device.

In some embodiments, the location data 1652 can include bay data, such as the last known bay the adapter cable was located in within a storage device, evidenced by the identification chip being read by a chip reader in the bay or associated with the bay.

In various embodiments, each cable profile 1636 can include cable data 1654. The cable data 1654 can include data related to the physical properties of the cable, such as average resistance of the cable determined in previous tests. The physical properties of the cable can be taken into consideration during a testing procedure to accurately account for specific aspects of the cable, such as the resistance of the cable. In some embodiments, the processing element is configured to automatically calibrate the analyzer based on the identity of the connected adapter cable(s).

The cable data 1654 can also include error data or warning data. If a cable is known to cause error or problems, data related to the errors or the problems (e.g., type of error, when the error occurred, if the cable has been repaired or fixed) can be stored in the cable profile. If the system detects a user is about to use a faulty or problem adapter cable, a warning can be presented to the user through a user interface.

### Probe

Various embodiments can include a probe that includes one or more chip readers, similar to a chip reader on the analyzer. In some embodiments, the probe can be a handheld probe. In some embodiments, the probe can include a user interface, such as a display screen.

In some embodiments, the probe can be used to determine the identify of an adapter cable by reading the identification chip that is attached to or embedded within the adapter cable. Upon determining the identity of the adapter cable, the system can instruct a user where the adapter cable should be moved to, such as where it should be stored or if it should be used in a subsequent test.

### Chip

In various embodiments, the identification chip can include a 1-Wire chip, such as the Dallas 1-Wire®. In various embodiments, the 1-Wire chip uses one wire for signaling and power. In some embodiments, the identification chip can include read and write capabilities. In some embodiments, the identification chip can include a memory component. In some embodiments, the identification chip can include read only capabilities, such as a RFID chip.

### Identification Chip Readers

Various options are contemplated for the implementation of chip readers compatible with identification chips integrated into the adapter cables described herein. In some embodiments, the chip reader is disposed within the analyzer housing and configured to interface directly with the identification chip during mechanical engagement of the analyzer connector of the adapter cable. The chip reader may utilize mating electrical contacts arranged to align with corresponding contacts on the identification chip's package, providing direct electrical connectivity for the transmission of identification data.

In certain configurations, the chip reader can be implemented as an integrated magnetic-coupling reader, wherein magnetic contacts ensure reliable alignment and secure engagement between the adapter cable connector and the analyzer's chip reader interface. The magnetic coupling may provide both the physical connection and the required electrical path to initiate a read operation of the identification chip. Such arrangements may reduce wear on physical contacts and may be advantageous in environments subject to frequent connection and disconnection of adapter cables.

Other embodiments contemplate a chip reader using spring-loaded or pogo-pin contacts enclosed within a recess of the analyzer connector, arranged so that, upon insertion of the adapter cable, the identification chip is pressed into contact with the pogo pins. The spring-loaded contacts may maintain positive pressure against the identification chip surface, ensuring a durable and consistent electrical interface even in the presence of vibration or slight misalignment.

In some alternative embodiments, the chip reader may be configured for wireless communication with identification chips supporting radio frequency communication protocols, such as RFID or NFC. In such embodiments, the chip reader may incorporate an inductive loop or antenna structure positioned adjacent to the cable connection interface, establishing a communication channel with the identification chip when the adapter cable is brought within proximity of the reader. These wireless chip readers can support identification chip interrogation without the need for direct physical electrical contacts, facilitating implementations where retrofitting existing cables with identification chips is desired, or where minimal modification to the analyzer connection interface is preferred.

In some implementations, the chip reader may include additional detection circuitry to sense the presence or absence of an adapter cable, as well as to differentiate between various types of identification chips (e.g., 1-Wire, I2C, RFID). This differentiation can facilitate adaptive operation of the analyzer or storage device, enabling dynamic adjustment of communication protocols or user prompts based on the identification chip technology detected. Moreover, the chip reader may incorporate status indicators, such as LEDs or audible signals, to provide confirmation of successful reading or alert the operator to connection errors.

Identification chip readers suitable for use within the described systems and methods can be realized in a variety of mechanical and electrical forms, including but not limited to: direct-contact electrical interfaces, magnetically coupled interfaces, spring-loaded probe arrangements, wireless (RF) reader configurations, and modular or replaceable assemblies. The selection of chip reader type can be adapted to the operational environment, desired identification chip technology, and system integration requirements.

### Methods

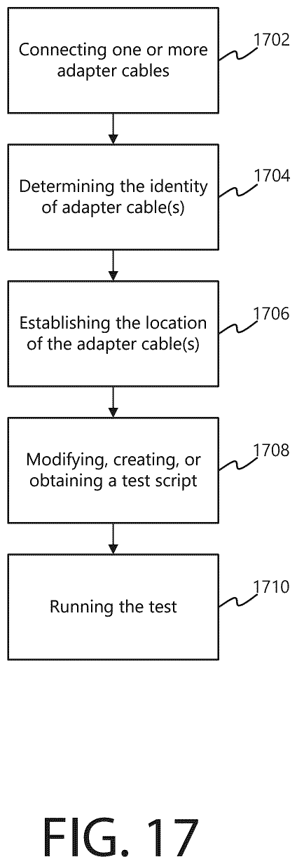

FIG. 17 shows a flow chart depicting a method for testing a wire harness in accordance with various embodiments herein. Various embodiments of a method can include connecting one or more adapter cables 1702, such as connecting one end of the adapter cable to an analyzer and the other end of the adapter cable to a wire harness or a unit under test.

The method can further include determining the identity of the connected adapter cable(s) 1704, such as by reading an identification chip on each adapter cable with a chip reader of the analyzer.

The method can further include determining the location of the connected adapter cable(s) 1706, such as by reading an identification chip on each adapter cable with a chip reader that is associated with a specific location on the analyzer.

Prior to running a test, an accurate test script is needed for the analyzer to properly run the test. The method can further include modifying, creating, or obtaining a test script 1708. The accurate test script can take into consideration which adapter cables are being used and their locations on the analyzer.

In some embodiments, a test script is pre-loaded or intended to be used. In such cases, the test script can be modified to accommodate the configuration of the adapter cables. In some embodiments, the processor of the analyzer can create a test script based on the known configuration of the adapter cables. In some embodiments, the processor of the analyzer can obtain a test script from a test script database that includes a plurality of test scripts, such as test scripts that run the same test but differ based on the adapter cable configurations. In such an embodiment, the obtained test script can match the known adapter cable configuration. The method can further include running or conducting the test 1710.

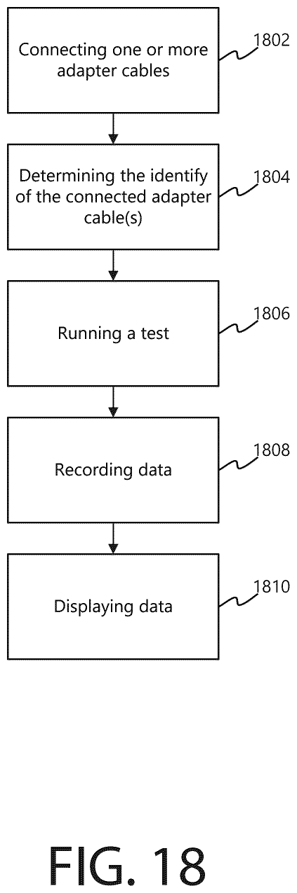

FIG. 18 shows a flow chart depicting a method for monitoring adapter cables in accordance with various embodiments herein. Various embodiments of a method can include connecting one or more adapter cables 1802, such as connecting one end of the adapter cable to an analyzer and the other end of the adapter cable to a wire harness or a unit under test.

The method can further include determining the identity of the connected adapter cable(s) 1804, such as by reading an identification chip on each adapter cable with a chip reader of the analyzer. The method can further include running or conducting the test 1806.

Prior to or after running a test, data regarding the adapter cable(s) in use can be recorded 1808. In some embodiments, the data can be recorded directly to the identification chip in or on the adapter cable. In some embodiments, the data can be recorded in an external database on an external server.

In some embodiments, the recorded data can include characteristics of the adapter cable. In some embodiments, the characteristics of the adapter cable can include the resistance of the adapter cable, the number of uses of the adapter cable, or errors associated with the tests that included the adapter cable.

In some embodiments, the method can further include displaying data on a user interface 1810. In some embodiments, the method can include displaying a warning, such as to replace an adapter cable or that an adapter cable is nearing the end of its useful life. In some embodiments, the method can include modifying a test script based on the recorded data. In some embodiments, the displayed data can include a potential problem associated with an adapter cable, such as if a failure commonly occurs while the specific adapter cable is in use.

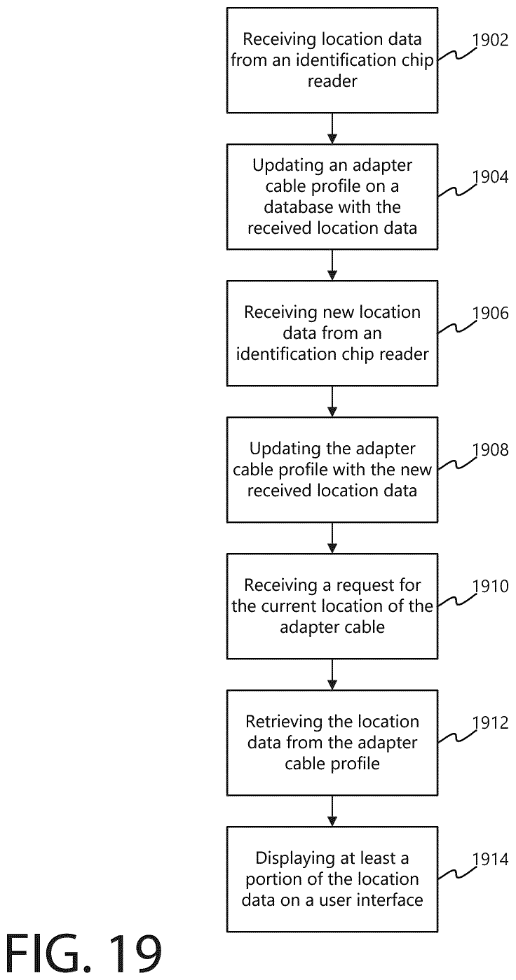

FIG. 19 shows a flow chart depicting a method for monitoring the location of an adapter cable in accordance with various embodiments herein.

In various embodiments, the method can include receiving location data from an identification chip reader 1902. In various embodiments, receiving location data from an identification chip reader can include detecting the unique identifier associated with an identification chip attached to or embedded within an adapter cable when the identification chip is within reading proximity or physical contact with the identification chip reader. For example, as an adapter cable is physically connected to an analyzer, placed into a storage bay, or moved past a doorway, the identification chip reader electronically communicates with the identification chip and retrieves the unique identifier. The identification chip reader may also include additional data regarding its own identity or location, such as a device identifier, storage bay number, room designation, or building identifier. The system can generate a data record that includes both the identification of the adapter cable (derived from the identification chip) and the current location or status of the identification chip reader.

In various embodiments, the method can include updating an adapter cable profile on a database with the received location data 1904. Upon receiving this location data from an identification chip reader, the method can include updating the corresponding adapter cable profile stored in a database. The system associates the received location data with the adapter cable profile by matching the unique identifier of the adapter cable received from the identification chip with the profile in the database. The adapter cable profile can include records of previous locations and use history of the cable. When new location data is received, the system creates or appends a log entry in the adapter cable profile that includes the time the location was detected, the identity or status of the chip reader, and any relevant contextual data such as which room, building, storage device, or analyzer port the cable was detected at. In some embodiments, the new location may also be marked as the current or last known location in the profile. This updating allows the system to maintain a current and historical record of the whereabouts of each adapter cable, supporting functions such as real-time asset tracking, retrieval history, and location-based inventory management.

In various embodiments, the method can include receiving new location data from an identification chip reader 1906. The identification chip reader from step 1906 can be the same identification chip reader in step 1902. In other situations, the identification chip reader from step 1906 is a different identification chip reader than in step 1902.

In various embodiments, the method can include updating the adapter cable profile with the new received location data 1908. In various embodiments, the method can include receiving a request for the current location of the adapter cable 1910. In various embodiments, the method can include retrieving the location data from the adapter cable profile 1912. In various embodiments, the method can include displaying at least a portion of the location data on a user interface 1914.

In various additional embodiments, methods for obtaining new data related to adapter cable usage, condition, and location can be implemented through automated or semi-automated processes during handling, testing, or storage of the cables. For example, a method may include periodically interrogating the identification chip of each adapter cable via dedicated chip readers situated at strategic process points, such as during transport through facility entry points, at operator workstations, or at quality control stations. As adaptor cables are moved between test sites or storage areas, each passage past a chip reader can trigger the creation of an event log that includes not only updated location data, but also contextual operational data, such as timestamp, operator identifier (if authenticated personnel are present), environmental conditions, or metadata from connected testing equipment. Such contextual event data can be used to refine tracking and condition-based maintenance strategies.

Additionally, methods for obtaining new data specific to cable integrity and operational health can be carried out by implementing periodic, automated diagnostic procedures. These procedures may involve the analyzer initiating a baseline resistance check or signal integrity test every time an adapter cable is connected or prior to test script execution. Diagnostic results can be written to either the identification chip memory or to an associated database record, together with metadata such as the date, time, and test parameters. Recurrent data collection of this type enables trend analysis for gradual cable degradation and supports predictive maintenance tasks.

In another contemplated method, periodic synchronization between local storage on identification chips and centralized databases may be performed, particularly where network connectivity is intermittent or certain operations are conducted in offline mode. When adapter cables are later returned to network-connected environments, any use history, diagnostic data, or location logs temporarily stored in chip memory are uploaded in bulk to the central database, ensuring continuity and completeness of the cable profile records.

It should be noted that, as used in this specification and the appended claims, the singular forms “a,” “an,” and “the” include plural referents unless the content clearly dictates otherwise. It should also be noted that the term “or” is generally employed in its sense including “and/or” unless the content clearly dictates otherwise.

It should also be noted that, as used in this specification and the appended claims, the phrase “configured” describes a system, apparatus, or other structure that is constructed or configured to perform a particular task or adopt a particular configuration. The phrase “configured” can be used interchangeably with other similar phrases such as arranged and configured, constructed and arranged, constructed, manufactured and arranged, and the like.

All publications and patent applications in this specification are indicative of the level of ordinary skill in the art to which this invention pertains. All publications and patent applications are herein incorporated by reference to the same extent as if each individual publication or patent application was specifically and individually indicated by reference.

As used herein, the recitation of numerical ranges by endpoints shall include all numbers subsumed within that range (e.g., 2 to 8 includes 2.1, 2.8, 5.3, 7, etc.).

The headings used herein are provided for consistency with suggestions under 37 CFR 1.77 or otherwise to provide organizational cues. These headings shall not be viewed to limit or characterize the invention(s) set out in any claims that may issue from this disclosure. As an example, although the headings refer to a “Field,” such claims should not be limited by the language chosen under this heading to describe the so-called technical field. Further, a description of a technology in the “Background” is not an admission that technology is prior art to any invention(s) in this disclosure. Neither is the “Summary” to be considered as a characterization of the invention(s) set forth in issued claims.

The embodiments described herein are not intended to be exhaustive or to limit the invention to the precise forms disclosed in the following detailed description. Rather, the embodiments are chosen and described so that others skilled in the art can appreciate and understand the principles and practices. As such, aspects have been described with reference to various specific and preferred embodiments and techniques. However, it should be understood that many variations and modifications may be made while remaining within the spirit and scope herein.

1. A testing system for evaluating electrical wiring systems, comprising:
an analyzer unit, wherein the analyzer unit comprises:
a plurality of test pins,
an identification chip reader, wherein the identification chip reader is configured to read and determine the identity of an identification chip, and
a processing element; and
a first adapter cable, wherein the first adapter cable comprises:
an analyzer interface, wherein the analyzer interface is configured to connect with a portion of the plurality of test pins,
a UUT interface,
a central cable extending between and electrically coupling the analyzer interface with the UUT interface, and
an identification chip coupled to the analyzer interface, the UUT interface, or the central cable, wherein the identification chip comprises a unique identifier;
a second adapter cable, wherein the second adapter cable comprises:
an analyzer interface, wherein the analyzer interface is configured to connect with a portion of the plurality of test pins,
a UUT interface,
a central cable extending between and electrically coupling the analyzer interface with the UUT interface, and
an identification chip coupled to the analyzer interface, the UUT interface, or the central cable, wherein the identification chip comprises a unique identifier;
wherein the analyzer interface of the first adapter cable is structurally different from the analyzer interface of the second adapter cable,
wherein a connection of the identification chip reader is structurally different from the plurality of test pins.

2. The testing system of claim 1, wherein the identification chip of the first adapter cable is disposed within the central cable.

3. The testing system of claim 1, wherein the identification chip of the first adapter cable is disposed within the analyzer interface.

4. The testing system of claim 1, wherein the identification chip of the first adapter cable is coupled to the first adapter cable with an extension.

5. The testing system of claim 1, wherein the identification chip reader requires physical contact of the identification chip reader with the identification chip.

6. The testing system of claim 1, wherein the identification chip of the first adapter cable and/or the identification chip of the second adapter cable is a 1-wire chip.

7. The testing system of claim 1, wherein the identification chip of the first adapter cable and/or the identification chip of the second adapter cable includes read-only capabilities.

8-9. (canceled)

10. The testing system of claim 1, wherein the identification chip of the first adapter cable and/or the identification chip of the second adapter cable comprises a memory component.

11. The testing system of claim 1, wherein the plurality of test pins are divided into a plurality of groups, wherein each group comprises at least two test pins and at least one identification chip reader.

12. The testing system of claim 11, wherein the analyzer interface of the first adapter cable is configured to interface with at least two different groups simultaneously.

13. The testing system of claim 12, wherein the analyzer interface of the second adapter cable is configured to interface with only one group at a time.

14. The testing system of claim 1, further comprising a user interface electrically coupled to the analyzer, wherein the user interface is configured to display test results to a user.

15. The testing system of claim 1, wherein the analyzer interface of each adapter cable includes a locking mechanism to secure the adapter cable to the analyzer unit.

16. The testing system of claim 1, wherein each UUT interface is configured to connect to a different configuration of electrical wiring system.

17. The testing system of claim 1, wherein the processing element is configured to automatically calibrate the analyzer unit based on the identity of the connected adapter cables.

18. A testing system for evaluating electrical wiring systems, comprising:
a storage unit, wherein the storage unit defines an interior volume, wherein the interior volume is configured to house one or more adapter cables, wherein the storage unit comprises an identification chip reader, wherein the identification chip reader is configured to read and determine the identity of an identification chip, and a network interface;
a first adapter cable, wherein the first adapter cable comprises:
an analyzer interface,
a UUT interface,
a central cable extending between and electrically coupling the analyzer interface with the UUT interface, and
an identification chip coupled to the analyzer interface, the UUT interface, or the central cable, wherein the identification chip comprises a unique identifier;
a second adapter cable, wherein the second adapter cable comprises:
an analyzer interface,
a UUT interface,
a central cable extending between and electrically coupling the analyzer interface with the UUT interface, and
an identification chip coupled to the analyzer interface, the UUT interface, or the central cable, wherein the identification chip comprises a unique identifier;
wherein the analyzer interface of the first adapter cable is structurally different than the analyzer interface of the second adapter cable;
wherein the first adapter cable and the second adapter cable are disposed within the storage unit;
wherein the identification chip reader of the storage unit requires physical contact of the identification chip reader with the identification chip.

19. The testing system of claim 18, wherein the interior volume of the storage unit is divided into a plurality of bays, wherein each bay comprises an identification chip reader.

20. The testing system of claim 18, wherein the network interface of the storage unit is configured for communication with an external database.

21. A method for evaluating electrical wiring systems, comprising:
connecting one or more adapter cables to an analyzer unit;
determining the identity of the one or more adapter cables connected to the analyzer unit by reading a unique identification chip on each of the adapter cables with an identification chip reader of the analyzer;
determining the location of the connection between the analyzer and each of the one or more adapter cables;
modifying, creating, or obtaining a test procedure in accordance with the determined identities of and the locations of each of the one or more adapter cables; and
running a test.

22. The method of claim 21, further comprising:
recording data in response to running the test; and
displaying, on a user interface, at least a portion of the data that was recorded.

23-27. (canceled)
